(19) United States
(12) Patent Application Publication
(10) Pub. No.: US 2026/0140456 A1
(43) Pub. Date: May 21, 2026

(54) MIRROR SYSTEM, METHOD FOR OPERATING A MIRROR SYSTEM, PROJECTION LENS FOR A MICROLITHOGRAPHIC PROJECTION EXPOSURE SYSTEM, AND COMPUTER PROGRAM PRODUCT

(71) Applicant: Carl Zeiss SMT GmbH, Oberkochen (DE)

(72) Inventors: Werner WEISS, Ulm (DE); Johannes SCHURER-KOCH, Heidenheim an der Brenz (DE)

(21) Appl. No.: 19/446,176

(22) Filed: Jan. 12, 2026

Related U.S. Application Data
(63) Continuation of application No. PCT/EP2024/066156, filed on Jun. 12, 2024.

(30) Foreign Application Priority Data
Jul. 19, 2023 (DE) 10 2023 206 859.1

(51) Int. Cl. G03F 7/00; G02B 7/18

(52) U.S. Cl. CPC G03F 7/70891; G02B 7/1815; G03F 7/70233; G03F 7/70316; G03F 7/70325; G03F 7/70525; G03F 7/7085; G03F 7/7095

(57) ABSTRACT

A mirror system comprises an EUV mirror, a temperature sensor, a control unit and a temperature-control module. The EUV mirror has a mirror body and an optical surface on the mirror body. The temperature sensor determines a measured temperature value via the temperature of the mirror body and transmits the measured temperature value to the control unit. The temperature-control module is actuated by control commands so that the temperature-control module influences the temperature of the mirror body. In a first operating state of the mirror system, the control unit determines the control commands by processing a first temperature setpoint value for the temperature of the mirror body. In a second operating state of the mirror system, the control unit determines the control commands by processing a second temperature setpoint value for the temperature of the mirror body.

### CROSS-REFERENCE TO RELATED APPLICATIONS

The present application is a continuation of, and claims benefit under 35 USC 120 to, international application No. PCT/EP2024/066156, filed Jun. 12, 2024, which claims benefit under 35 USC 119 of German Application No. 10 2023 206 859.1, filed Jul. 19, 2023. The entire disclosure of each of these applications is incorporated by reference herein.

### FIELD

The disclosure relates to a mirror system, a method for operating a mirror system, a projection lens for a microlithographic projection exposure apparatus, and a computer program product.

### BACKGROUND

Microlithography projection exposure apparatuses are utilized for the production of integrated circuits with particularly small structures. In some cases, a mask (=reticle) illuminated by very short-wave extreme ultraviolet radiation (EUV radiation) is imaged onto a lithography object in order to transfer the mask structure to the lithography object.

An EUV projection exposure apparatus usually comprises a plurality of EUV mirrors having an optical surface at which the radiation is reflected. The EUV mirrors typically have a precisely defined shape and are precisely positioned in order that the imaging of the mask onto the lithography object is of sufficient quality.

Some of the EUV radiation incident on the optical surface of the mirror is reflected and some is absorbed. The absorbed portion of the EUV radiation can bring about mirror body heating. In general, temperature changes of a body are accompanied by a thermal deformation. This is usually unwanted in the case of microlithographic projection exposure apparatus mirrors because the wavefront of the EUV radiation reflected at the optical surface is usually modified when the geometric shape of the mirror changes. This usually leads to a reduction in the imaging quality.

An issue is that the image quality is not equally good in different operating states of the projection exposure apparatus.

### SUMMARY

The disclosure seeks to provide an improved mirror system, method for operating a mirror system, projection lens for a microlithographic projection exposure apparatus, and computer program product.

In an aspect, the disclosure provides a mirror system comprising an EUV mirror, a temperature sensor, a control unit and a temperature-control module. The EUV mirror has a mirror body and an optical surface formed on the mirror body. The temperature sensor determines a measured temperature value via the temperature of the mirror body and transmits the measured temperature values to the control unit. The control unit evaluates the measured temperature value in order to determine control commands for the temperature-control module. The temperature-control module is actuated by the control commands so that the temperature-control module influences the temperature of the mirror body. In a first operating state of the mirror system, the control unit determines the control commands by processing a first temperature setpoint value for the temperature of the mirror body. In a second operating state of the mirror system, the control unit determines the control commands by processing a second temperature setpoint value for the temperature of the mirror body.

The disclosure has identified that the thermal deformations of the mirror body associated with a change in temperature can be used to improve the image quality of the projection lens. The disclosure proposes to provide different, specifically adapted temperature setpoint values for the mirror body for different operating states of the mirror system.

The mirror body may comprise a material of which at least 70%, such as at least 90%, is a ZCT material, based on the mass of the mirror body. ZCT material refers to a material whose coefficient of thermal expansion has a zero crossing (zero-crossing temperature).

It is generally conventional to bring the mirrors of a projection exposure apparatus to a temperature close to the ZCT during operation. This can mean that slight fluctuations in the temperature do not affect the geometric shape of the mirror body. This can mean that slight temperature fluctuations can be accepted without adversely affecting the image quality of the projection lens. The disclosure can be carried out in such a way that the first temperature setpoint value corresponds to the ZCT temperature and that the second temperature setpoint value deviates from the ZCT temperature.

In one embodiment, both the first temperature setpoint value and the second temperature setpoint value deviate from the zero-crossing temperature of the ZCT material. The gap between the ZCT temperature and the nearest temperature setpoint value can be at least 0.2 K, such as at least 1 K, for example at least 2 K. If both temperature setpoint values deviate from the ZCT temperature, this can yield higher sensitivity, so that noticeable thermal deformation occurs even with small temperature changes.

The difference between the first temperature setpoint value and the second temperature setpoint value may be greater than 0.1 K, such as greater than 0.2 K, for example greater than 0.5 K. In general, the difference between the first temperature setpoint value and the second temperature setpoint value is not greater than 3 K, such as not greater than 2 K. The first temperature setpoint value and the second temperature setpoint value may relate to the mean temperature that the mirror body has at the optical surface.

The operation of a mirror system according to the disclosure may comprise multiple phases. In an idle state, in which the projection exposure apparatus is not in operation, the mirror body may have a rest temperature that may correspond to the ambient temperature. For example, the ambient temperature may be room temperature, i.e. in the order of 20° C. When the projection exposure apparatus is started up, a pre-heating phase can follow, in which the mirror body is heated so that the temperature approaches an operating temperature intended for operation. It is not necessary for the mirror body to be heated to a temperature that is identical to the operating temperature setpoint in the pre-heating phase.

The mirror system may comprise a heating device in the form of a so-called preheater, by which thermal energy can be supplied to the mirror body in the preheating phase. The preheater may be designed, for example, to guide suitable electromagnetic radiation, in particular infrared radiation, to the mirror body. It is also possible to supply the thermal energy using a heat transfer fluid. The heat transfer fluid may, for example, be guided through channels formed in the mirror body.

The first temperature setpoint value may be a setpoint value for the operating temperature, the second temperature setpoint value may be a setpoint value for the operating temperature. Operating temperature refers to a temperature that is sought as stationary state during operation of the projection exposure apparatus. When thermal energy is continuously supplied to the mirror body during operation of the projection exposure apparatus, the operating temperature is higher than the ambient temperature. For example, the operating temperature may be between 1 K and 20 K, such as between 3 K and 15 K, higher than the ambient temperature.

The operating temperature is generally dependent on the amount of heat supplied to the mirror body during operation of the projection exposure apparatus. This includes thermal energy from absorption of EUV radiation. This may also include thermal energy supplied to the mirror body using a heating device. The control unit may be designed to actuate the heating device in such a way that the heating power supplied to the mirror body is in a suitable ratio to the EUV radiation directed onto the mirror.

The operating temperature is also generally dependent on the amount of heat dissipated from the mirror body during operation of the projection exposure apparatus. This may include thermal energy that is radiated to the environment. This may also include thermal energy that is dissipated from the mirror body using suitable cooling devices. For example, the mirror body may comprise cooling channels through which a cooling fluid is routed during operation of the projection exposure apparatus. The control unit may be designed to actuate the heating device in such a way that the heating power supplied to the mirror body is in a suitable ratio to the thermal energy dissipated from the mirror body.

The heating device may be designed to transmit thermal radiation to the mirror body. The thermal radiation can be incident on the optical surface of the mirror, i.e. on the same surface on which the EUV radiation is incident. The heating device may be in the form of a sector heater, such that different areas of the optical surface can be exposed to thermal radiation independently of each other.

The mirror system can be operated in the first operating state with a first illumination setting and in the second operating state with an illumination setting. The illumination setting refers to the distribution of the EUV radiation over the cross section of the beam path. In general, the illumination setting of a microlithographic projection exposure apparatus is adjusted so that the radiation intensity over the illuminated surface is constant in the image plane, that is to say in particular on the surface of the lithographic object. In contrast, the angular distribution of the incoming radiation in the image plane may be different from illumination setting to illumination setting. The different angular distributions in the image plane can translate to different intensity distributions in the pupil plane.

In one embodiment, the EUV mirror of the mirror system according to the disclosure is a near-field EUV mirror in the beam path of the projection lens. A mirror is referred to as near-field when the distance measured along the beam path to the nearest field plane is smaller, such as smaller by less than a factor of 2, for example smaller by less than a factor of 3, than the distance to the nearest pupil plane.

With different illumination settings, the microlithographic projection exposure apparatus can be adapted to different applications, in particular to different types of lithographic objects. The illumination setting is derived in each case individually from the application case. The illumination setting of the first operating state may be, for example, an annular, a dipole or a quadrupole illumination setting. The illumination setting of the second operating state may be, for example, an annular, a dipole or a quadrupole illumination setting, wherein the illumination setting of the second operating state is different to the illumination setting of the first operating state. The various options for illumination settings can be combined with one another as desired under the operating states.

The first temperature setpoint value can be determined by describing the EUV mirror as a model. The model can be used to describe the geometric shape of the mirror body as a function of the temperature. The geometric shape can be determined as a function of a temperature distribution over the mirror body. In addition or as an alternative, the geometric shape can be determined as a function of the mean temperature on the optical surface of the mirror.

An optimization procedure can be performed to determine the temperature setpoint value. This procedure can be used to optimize the geometric shape of the mirror body by varying the temperature. Various parameters of the imaging beam path are considered as quality criteria for the optimization procedure. For example, those parameters of the imaging beam path which are not accessible to a correction within the rigid-body degrees of freedom of the mirror body can be suitable as a quality criterion.

In one embodiment, the optimization criterion is a minimization of a non-correctable error NCE_{Z2/Z3} within the rigid-body degrees of freedom of the mirror body, which is defined by applying the Zernike coefficients Z2, Z3 as follows.

$${NCE}_{Z 2 / Z 3} = \frac{1}{NA} {max}_{field} ( \vert {Z}_{2} ( field ) \vert , \vert {Z}_{3} ( field ) \vert )$$

It is also possible to pursue the optimization goal of minimizing a quality criterion referred to as RMS5, which is defined as follows.

$$RMS 5 = \sqrt{{\sum }_{i = 5}^{36} {ε}_{i} \cdot {Z}_{i}^{2} + {ε}_{i} \cdot {Z}_{49}^{2}} with {ε}_{i} = \frac{k}{2 ( n + 1 )}$$

In this case, εᵢ are the RMS weightings for the Zernike coefficients Zᵢ with a radial order n. The factor k has a value of 2 for spherical terms and otherwise has the value of 1.

Another possible variant would be to optimize the field profile coefficient k₁₃ in the Zernike decomposition of the wavefront aberration. If the aberration observed in the cross section of the EUV beam path is subjected to a Zernike decomposition, k₁₃ in the second Zernike polynomial Z₂(x) denotes the coefficient of the third power

$$dx ( x ) = - {Z}_{2} ( x ) / NA = {k}_{1} + {k}_{3} * x + {k}_{7} * {x}^{2} + {k}_{13} * {x}^{3} + residual function$$

The coefficient k₁₃ is the first field profile coefficient in the Zernike polynomial Z₂(x), which cannot be corrected within the rigid-body degrees of freedom of the EUV mirrors of the projection lens.

Other optimization criteria are possible. For example, certain performance variables can be adjusted to a predefined value. This may be useful, for example, to minimize discrepancies between different microlithographic projection exposure apparatus. In other application examples, optimization can be performed to specific user-specified use cases.

The second temperature setpoint value can be determined accordingly.

Optimization may be limited to optimizing a single mirror. Optimization across multiple mirrors is also possible. This can make use of the fact that errors from individual mirrors can balance one another out. The result of such an optimization procedure carried out over multiple mirrors can be optimized temperature setpoint values for each of the participating mirrors.

The control unit of the mirror system according to the disclosure may comprise a memory element in which data for the operation of the mirror system in different operating states are stored. For example, an assignment between the first operating state of the mirror system and the first temperature setpoint value can be stored in the memory element and an assignment between the second operating state of the mirror system and the second temperature setpoint can be stored in the memory element. The control unit can be configured in such a way that the correct assignment between operating states and setpoint temperatures is automatically made during operation.

The mirror system may have more than two operating states, such as at least three operating states, for example at least five operating states, with each operating state being assigned a temperature setpoint value. The features mentioned in connection with the first and second operating state can also apply to the other operating states.

The disclosure furthermore relates to a projection lens comprising a plurality of EUV mirrors used to image a reticle into an image plane. The projection lens comprises a mirror system of this type. The disclosure also relates to a microlithographic projection exposure apparatus having such a projection lens.

The disclosure also relates to a method for operating a mirror system, wherein the mirror system comprises an EUV mirror having a mirror body and an optical surface which is formed on the mirror body. A measured temperature value is determined via the temperature of the mirror body, wherein the measured temperature value is evaluated in order to actuate a temperature-control module so that the temperature-control module influences the temperature of the mirror body. In a first operating state of the mirror system, the control commands are determined by processing a first temperature setpoint value for the temperature of the mirror body. In a second operating state of the mirror system, the control commands are determined by processing a second temperature setpoint value for the temperature of the mirror body.

The disclosure also relates to a computer program product or a set of computer program products comprising program parts which, when loaded into a computer or into networked computers connected to a device according to the disclosure, are designed to perform the method according to the disclosure.

The disclosure encompasses developments of the mirror system with features that are described in the context of the method according to the disclosure. The disclosure encompasses developments of the method with features that are described in the context of the mirror system according to the disclosure.

### BRIEF DESCRIPTION OF THE DRAWINGS

The disclosure is described by way of example below on the basis of certain embodiments with reference to the accompanying drawings, in which:

FIG. 1 shows one embodiment of a projection exposure apparatus according to the disclosure;

FIG. 2 shows a schematic illustration of a mirror system according to the disclosure;

FIG. 3 shows a schematic illustration of the control unit of the mirror system from FIG. 2;

FIG. 4 shows a first exemplary embodiment; and

FIG. 5 shows a second exemplary embodiment.

### DETAILED DESCRIPTION

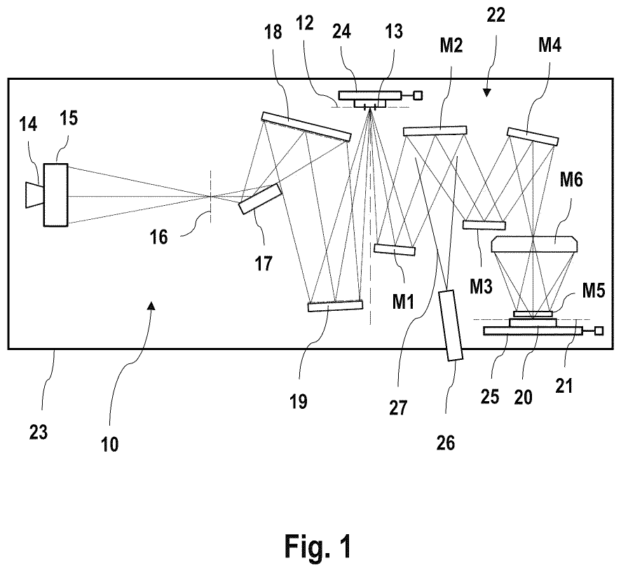

FIG. 1 schematically illustrates a microlithographic EUV projection exposure apparatus. The projection exposure apparatus comprises an exposure beam source 14, an illumination system 10 and a projection lens 22, which are operated jointly in a vacuum chamber 23. Negative pressure prevails in the vacuum chamber 23 during the operation of the EUV projection exposure apparatus.

The exposure beam source 14 generates electromagnetic radiation in the EUV range, i.e. at a wavelength of between 5 nm and 30 nm for example. The exposure radiation emanating from the exposure beam source 14 is focused into an intermediate focal plane 16 by way of a collector 15. Exposure radiation passing across the intermediate focal plane 16 is guided into an object plane 12 by the illumination system 10, with the result that an object field in the object plane 12 is illuminated with uniform radiation intensity.

The illumination system 10 comprises a deflection mirror 17 used to deflect the exposure radiation to a first facet mirror 18. A second facet mirror 19 is disposed downstream of the first facet mirror 18. The second facet mirror 19 is used to image the facets of the first facet mirror 18 into the object plane 12.

A mask, referred to as reticle 13, is arranged in the object field, and is imaged into an image plane 21 by way of a plurality of mirrors M1-M6 of the projection lens 22. A structure formed on the reticle 13 is transferred to a radiation-sensitive layer of a wafer 20 arranged in the image plane 21. The reticle 13 is suspended from a first scanning device 24, and the wafer 20 is at rest on a second scanning device 25 such that the wafer 20 can be exposed in a scanning procedure during which the reticle 13 and the wafer 20 are moved synchronously with one another.

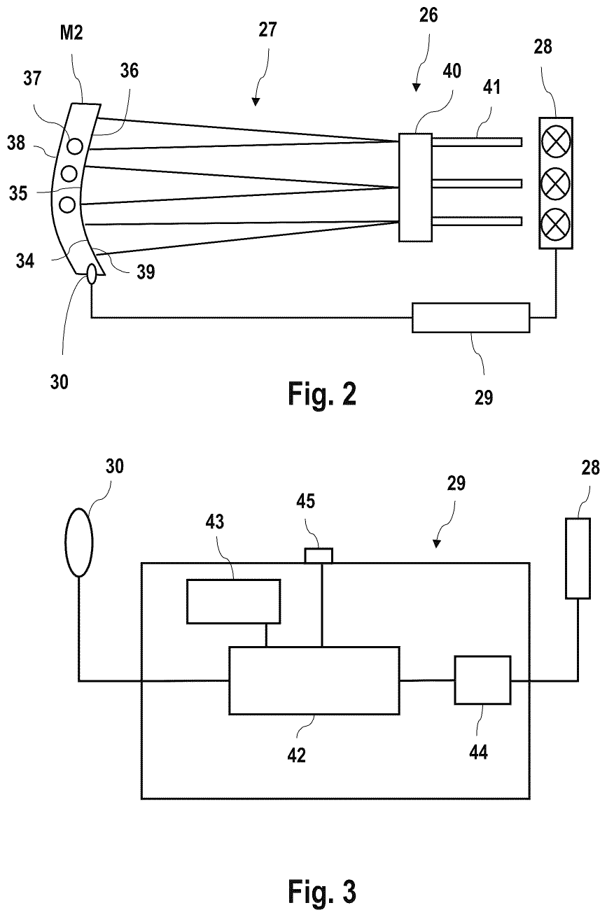

The various mirrors of the projection exposure apparatus at which the exposure radiation is reflected are configured as EUV mirrors. The EUV mirrors comprise, as shown in the mirror system shown in FIG. 2 in the example of the mirror M2, a mirror body 38 and an optical surface 39 which is formed on the mirror body 38 and made of a highly reflective coating. This may be a multilayer coating, in particular a multilayer coating having alternating layers of molybdenum and silicon. The EUV mirrors reflect approximately 70% of the incident EUV radiation. The approximately 30% that remains is absorbed and leads to heating of the EUV mirrors.

The EUV mirrors M1-M6 of the projection lens 22 may comprise (or consist of) a material that exhibits ultra-low thermal expansion (ultra-low expansion material), for example a titanium silicate glass marketed under the name ULE™ by Corning Inc. During operation of the projection lens, the temperature of the mirror body can be set to a value close to the so-called zero-crossing temperature (ZCT). At this zero-crossing temperature, which can be specified individually for each mirror, the coefficient of thermal expansion has a zero crossing, in the vicinity of which changes in temperature cause no or only negligible thermal expansion of the material of the mirror body.

In order to keep the temperature of the mirror body at the specified value, an active cooling system is provided, in which a cooling liquid is passed through the mirror body. This is indicated schematically in FIG. 2 by the cooling channels 37 formed in the mirror body 38.

The projection exposure apparatus comprises a heating device 26 designed to direct infrared radiation 27 onto the optical surface 39 of the EUV mirror M2 in order to locally heat the EUV mirror M2. The wavelength of the infrared radiation may be between 1050 nm and 1600 nm, for example. The heating power may be between 2 W and 100 W, for example. Local heating causes a local thermal expansion, which can be specifically designed so that the temperature of the mirror body 38 assumes a setpoint value.

According to FIG. 2, the heating device 26 comprises an optical module 40 to which a plurality of light guides 41 is connected. An infrared radiation source 28 comprises multiple infrared emitters, each of which feeds infrared radiation into one of the light guides 41. The optical module 26 comprises for each of the light guides 41 an optical element, for example in the form of a lens element, by which the infrared radiation emerging from the light guide 41 is formed into an infrared beam of rays used to illuminate a particular surface region 34, 35, 36 on the optical surface 39 of one of the mirrors M1-M6. The heating device 26 forms a temperature-control module of the mirror system in the context of the disclosure. In the simplified illustration in FIG. 2, the heating device 26 is shown with three heating channels. In practice, the number of heating channels of the heating device 26 may be greater.

The mirror system comprises a control unit 29 which actuates the infrared radiation sources 28 depending on different input variables. FIG. 2 shows by way of example a sensor 30 which measures a measured value via a state variable of the EUV mirror 20, such as the temperature, for example, and supplies same to the control unit 29. Through appropriate control signals from the control unit 29, the power of the infrared radiation sources 28 can be adjusted as desired.

A mirror system according to the disclosure comprises a control unit 29 to which measured values from a temperature sensor 30 are supplied. The temperature sensor 30, which is illustrated only schematically in FIG. 2, may comprise a plurality of sensor elements distributed over the optical surface 39 of the relevant mirror M1-M6, from which sensor elements an average value of the temperature of the mirror body 38 on the optical surface 39 can be determined. The sensor elements can be integrated into the mirror body 38, can be arranged on the surface of the mirror body 38 or can measure contactlessly.

The measured value over the average temperature of the mirror body 38 on the optical surface 39 is supplied to a central computer 42 of the control unit 29. The central computer 42 compares the measured temperature with a temperature setpoint value stored in a memory element 43. The deviation is used to determine a control command which is sent to a command generator 44. The command generator 44 actuates the radiation source 28, which sets the heating power directed to the mirror body 38 according to the control command.

The mirror system can be switched over between different operating states, which correspond to different illumination settings of the projection exposure apparatus, via an input interface 45. Depending on the operating states, different temperature setpoint values are stored in the memory element 43. The central computer 42 is designed to automatically read out from the memory element 43 the temperature setpoint value which is suitable for the selected operating state. Depending on the temperature setpoint value, different control commands result from the sensor 30 with the same measured value, using which the infrared radiation source 28 is actuated.

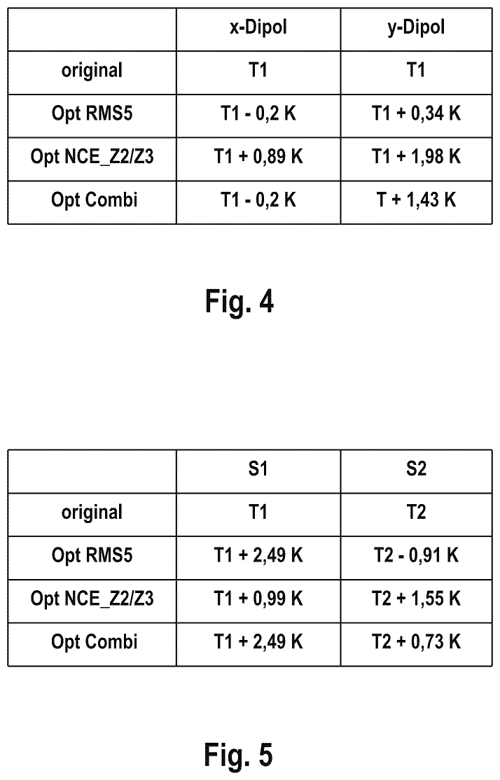

The temperature setpoint values stored in the memory element 43 can be determined using an optimization method using which a quality criterion is optimized. The table in FIG. 4 is based on an optimization method according to the disclosure, which has been carried out using an optical system using which a photomask is imaged via a plurality of mirrors in an object plane. With conventional procedures, a temperature setpoint value T is determined for each of the mirrors and remains constant regardless of the respective operating state of the optical system. In Table 4, this is indicated in line 1 for the temperature setpoint value T1, the value of which remains unchanged regardless of whether the optical system is operated with an x-dipole illumination setting or with a y-dipole illumination setting.

In a first attempt, the optimization method was carried out using the RMS5 quality criterion. The x-dipole produces a new temperature setpoint value which is 0.2 K lower than the previous temperature setpoint value T1 and which results in a reduction in the aberration of the RMS5 by about one third. For the y-dipole, on the other hand, the temperature setpoint value increases by 0.34 K, which is associated with a reduction in the aberration of the RMS5 by about 40%.

If the optimization is performed instead using the NCE_{Z2/Z3} quality criterion, the x-dipole increases the temperature setpoint by 0.89 K and the aberration of the NCE_{Z2/Z3} is reduced by more than 60%. For the y-dipole, the temperature setpoint value is increased by 1.98 K and the aberration is reduced by more than 70%. The relevant temperature values are given in line 3 of FIG. 4.

In line 4 of FIG. 4, the optimization method was carried out in such a way that a joint optimization of the quality criteria RMS5 and NCE_{Z2/Z3} was sought. For the x-dipole, the temperature setpoint value decreases by 0.2 K. For the y-dipole, the temperature setpoint value increases by 1.43 K.

FIG. 5 shows which temperature setpoint values are determined when joint optimization is performed for two other mirrors S1, S2 of the same optical system. In the case of optimization using the quality criterion RMS5, the temperature setpoint value T1 for the first mirror S1 increases by 2.49 K and the temperature setpoint value T2 for the second mirror S2 decreases by 0.91 K; see column 2 in FIG. 5. An application of the quality criterion NCE_{Z2/Z3} results in an increase of the temperature setpoint value T1 by 0.99 K and an increase of the temperature setpoint value T2 by 1.55 K. Optimization of the two mirrors S1, S2 in combination with the quality criteria RMS5 and NCE_{Z2/Z3} results in an increase of the temperature setpoint value T1 by 2.49 K and an increase of the temperature setpoint value T2 by 0.73 K.

What is claimed is:

1. A mirror system, comprising:
an EUV mirror comprising a mirror body and an optical surface supported by the mirror body;
a temperature sensor;
a control unit; and
a temperature-control module,
wherein:
the temperature sensor is configured to determine a temperature value of the mirror body;
the temperature sensor is configured to transmit the temperature value of the mirror body to the control unit;
the control unit is configured to determine control commands for the temperature-control module;
the temperature-control module is actuatable by the control commands so that the temperature-control module influences a temperature of the mirror body;
in a first operating state of the mirror system, the control unit is configured to determine the control commands based the temperature value of the mirror body and a first temperature setpoint value for the temperature of the mirror body;
in a second operating state of the mirror system, the control unit is configured to determine the control commands based the temperature value of the mirror body and a second temperature setpoint value for the temperature of the mirror body;
the first operating state is different from the second operating state; and
the first setpoint value is different from the second setpoint value.

2. The mirror system of claim 1, wherein, based on a mass of the mirror body, at least 70% of the mirror body comprises a ZCT material.

3. The mirror system of claim 2, wherein each of the first and second temperature setpoint values deviates from a zero-crossing temperature of the ZCT material.

4. The mirror system of claim 1, wherein a difference between the first temperature setpoint value and the second temperature setpoint value is greater than 0.1 Kelvin.

5. The mirror system of claim 1, wherein the first temperature setpoint value is a setpoint value for an operating temperature of the mirror body, and the second temperature setpoint value is a setpoint value for the operating temperature of the mirror body.

6. The mirror system of claim 1, wherein:
in the first operating state, the mirror system has a first illumination setting; and
in the second operating state, the mirror system has a second illumination setting different from the first illumination setting.

7. The mirror system of claim 1, wherein the EUV mirror comprises a near-field EUV mirror.

8. The mirror system of claim 1, wherein the first temperature setpoint value is determinable by an optimization procedure.

9. The mirror system of claim 8, wherein the optimization procedure comprises an optimization criterion, and the optimization criterion is a minimization of a field profile coefficient k₁₃ in a Zernike decomposition of a wavefront aberration.

10. The mirror system of claim 8, wherein the EUV system comprises a plurality of EUV mirrors, and the mirror system is configured to perform joint optimization over the plurality of EUV mirrors.

11. The mirror system of claim 8, the second temperature setpoint value is determinable by an optimization procedure.

12. The mirror system of claim 8, wherein, based on a mass of the mirror body, at least 70% of the mirror body comprises a ZCT material.

13. The mirror system of claim 1, wherein the mirror body comprises cooling channels.

14. The mirror system of claim 1, wherein the temperature-control module comprises a sector heater.

15. A lens, comprising:
a mirror system according to claim 1,
wherein the lens is a microlithographic projection lens.

16. An apparatus, comprising:
an illumination system; and
a projection lens comprising a mirror system according to claim 1,
wherein the apparatus is a microlithographic projection exposure apparatus.

17. A method of using a microlithographic projection exposure apparatus comprising an illumination system and a projection lens, the method comprising:
using the illumination system to illuminate a structure of a mask in an object field of in an object plane of the projection lens; and
using the projection lens to project the illuminated structure of the mask onto a radiation-sensitive material in an image plane in an image field of the projection lens,
wherein the projection lens comprises a mirror system according to claim 1.

18. A method of operating a mirror system comprising an EUV mirror, the mirror comprising a mirror body and an optical surface supported by the mirror body, the mirror system further comprising a temperature-control module, the method comprising:
determining a temperature value of the mirror body;
sending control commands to the temperature-control module to influence a temperature of the mirror body,
wherein:
in a first operating state of the mirror system, the control commands are based the temperature value of the mirror body and a first temperature setpoint value for the EUV mirror;
in a second operating state of the mirror system, the control commands are based the temperature value of the mirror body and a second temperature setpoint value for the EUV mirror;
the first operating state is different from the second operating state; and
the first setpoint value is different from the second setpoint value.

19. One or more machine-readable hardware storage devices comprising instructions that are executable by one or more processing devices to perform operations comprising the method of claim 18.

20. A system, comprising:
one or more processing devices; and
one or more machine-readable hardware storage devices comprising instructions that are executable by the one or more processing devices to perform operations comprising the method of claim 18.
